(19) United States
(12) Patent Application Publication
(10) Pub. No.: US 2024/0084440 A1
(43) Pub. Date: Mar. 14, 2024

(54) APPARATUS AND A METHOD FOR PROVIDING NANO COATING ON A SURFACE

(71) Applicant: Harsh Vardhan SETHI, Mumbai (IN)

(72) Inventor: Harsh Vardhan SETHI, Mumbai (IN)

(21) Appl. No.: 18/385,237

(22) Filed: Oct. 30, 2023

Related U.S. Application Data
(63) Continuation of application No. PCT/IB2022/052697, filed on Mar. 24, 2022.

(30) Foreign Application Priority Data
Feb. 2, 2022 (IN) 202221005662

(51) Int. Cl. C23C 14/32

(52) U.S. Cl. CPC C23C 14/325; B82Y 30/00

(57) ABSTRACT

An apparatus and a method for providing nano coating on a surface is provided. The apparatus includes a spark head unit electrically coupled to a voltage source and mounted on a frame. The spark head unit includes electrode pairs composed of a predefined inorganic material. The electrode pairs are mounted on the spark head unit in a three-dimensional array format. The electrode pairs are adapted to provide a spark between electrodes of the corresponding electrode pairs to obtain a fused electrode material upon receiving a voltage from the voltage source. The electrode pairs are also adapted to deposit the fused electrode material obtained on a surface thereby providing nano coating on the surface. The fused electrode material includes oxides of the predefined inorganic material. The three-dimensional array format is adapted to provide non-uniform deposition of the fused electrode material on the surface.

### EARLIEST PRIORITY DATE

This Application claims priority from a Complete patent application filed in India having Patent Application No. 202221005662, filed on Feb. 2, 2022, and titled “AN APPARATUS AND A METHOD FOR PROVIDING NANO COATING ON A SURFACE”.

### FIELD OF INVENTION

Embodiments of the present disclosure relate to the field of nano coatings and more particularly to an apparatus and a method for providing nano coating on a surface.

### BACKGROUND

Light may be defined as electromagnetic radiations perceived by human eyes. The light may be emitted by objects such as lasers, lamps and sun. The light is a collection of small packets of energy known as photons. The photons may be released when electrons in the objects get excited upon receiving heat energy by the objects. Energy present in the light may be utilized for many applications such as power generation, heating, processing food materials and the like. Utilization of the light falling on a surface depends on factors such as amount of the light reflected by the surface, amount of the light scattered by the surface, amount of the light transmitted through the surface and cleanliness of the surface.

Reflection and transmission of the light by materials enclosing solar panels may reduce efficiency of the solar panels. Similarly, inability of the materials to reflect the light may undermine cooling applications and the inability of the materials to transmit the light may affect the heating applications. Further, efficiency of the solar panels, efficiency of heating applications and the efficiency of the cooling applications may be further related to cleanliness of the materials. Currently existing systems are inefficient to modify the utilization of the light falling on the surface. Also, self-cleaning ability of the surface is sluggish which in turn demands considerable number of resources for keeping the surface clean.

Hence, there is a need for an improved apparatus and a method for providing nano coating on a surface to address the aforementioned issue(s).

### BRIEF DESCRIPTION

In accordance with an embodiment of the present disclosure, an apparatus for providing nano coating on a surface is provided. The apparatus includes a spark head unit electrically coupled to a voltage source and mounted on a frame. The spark head unit includes one or more electrode pairs composed of a predefined inorganic material. The one or more electrode pairs are mounted on the spark head unit in a three dimensional array format. The one or more electrode pairs are adapted to provide a spark between electrodes of the corresponding one or more electrode pairs to obtain a fused electrode material upon receiving a voltage from the voltage source. The one or more electrode pairs are also adapted to deposit the fused electrode material obtained on a surface thereby providing nano coating on the surface. The fused electrode material includes oxides of the predefined inorganic material. The three dimensional array format is adapted to provide non-uniform deposition of the fused electrode material on the surface.

In accordance with another embodiment of the present disclosure, a method for providing nano coating on a surface is provided. The method includes aligning, by a robotic structure, a spark head unit mounted on a frame with a surface to set up the one or more electrode pairs composed of titanium in proximity with the surface. The method also includes providing, by a voltage source, a nano coating on the surface by supplying a voltage to the spark head unit upon setting up the one or more electrode pairs in proximity with the surface.

To further clarify the advantages and features of the present disclosure, a more particular description of the disclosure will follow by reference to specific embodiments thereof, which are illustrated in the appended figures. It is to be appreciated that these figures depict only typical embodiments of the disclosure and are therefore not to be considered limiting in scope.

The disclosure will be described and explained with additional specificity and detail with the appended figures.

### BRIEF DESCRIPTION OF THE DRAWINGS

The disclosure will be described and explained with additional specificity and detail with the accompanying figures in which:

FIG. 1 is a schematic representation of an apparatus for providing nano coating on a surface in accordance with an embodiment of the present disclosure:

FIG. 2 is a schematic representation of one embodiment of the system of FIG. 1, depicting isometric view of a spark head unit in accordance with an embodiment of the present disclosure;

FIG. 3 is a schematic representation of another embodiment of the system of FIG. 1, depicting side view of the spark head unit in accordance with an embodiment of the present disclosure;

FIG. 4 is a schematic representation of yet another embodiment of the system of FIG. 1, depicting top view of the spark head unit in accordance with an embodiment of the present disclosure;

FIG. 5 is a schematic representation of yet another embodiment of the system of FIG. 1, depicting front view of the spark head unit in accordance with an embodiment of the present disclosure;

FIG. 6 is a schematic representation of yet another embodiment of the system of FIG. 1, depicting circuital arrangement of the spark head unit, a voltage source, one or more ceramic capacitors, and one or more pulse coils in accordance with an embodiment of the present disclosure;

FIG. 7 is a schematic representation of yet another embodiment of the system of FIG. 1, depicting microscopic view of the nano coating on the surface; and

FIG. 8 is a flow chart representing the steps involved in a method for providing nano coating on a surface in accordance with an embodiment of the present disclosure.

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show only those specific details that are pertinent to understanding the embodiments of the present disclosure so as not to obscure the figures with details that will be readily apparent to those skilled in the art having the benefit of the description herein.

### DETAILED DESCRIPTION

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated system, and such further applications of the principles of the disclosure as would normally occur to those skilled in the art are to be construed as being within the scope of the present disclosure.

The terms “comprises”, “comprising”, or any other variations thereof, are intended to cover a non-exclusive inclusion, such that a process or method that comprises a list of steps does not include only those steps but may include other steps not expressly listed or inherent to such a process or method. Similarly, one or more devices or sub-systems or elements or structures or components preceded by “comprises . . . a” does not, without more constraints, preclude the existence of other devices, sub-systems, elements, structures, components, additional devices, additional sub-systems, additional elements, additional structures, or additional components. Appearances of the phrase “in an embodiment”, “in another embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are only illustrative and not intended to be limiting.

In the following specification and the claims, reference will be made to a number of terms, which shall be defined to have the following meanings. The singular forms “a”, “an”, and “the” include plural references unless the context clearly dictates otherwise.

Embodiments of the present disclosure relate to an apparatus and a method for providing nano coating on a surface. In accordance with an embodiment of the present disclosure, an apparatus and a method for providing nano coating on a surface is provided. The apparatus includes a spark head unit electrically coupled to a voltage source and mounted on a frame. The spark head unit includes one or more electrode pairs composed of a predefined inorganic material. The one or more electrode pairs are mounted on the spark head unit in a three dimensional array format. The one or more electrode pairs are adapted to provide a spark between electrodes of the corresponding one or more electrode pairs to obtain a fused electrode material upon receiving a voltage from the voltage source. The one or more electrode pairs are also adapted to deposit the fused electrode material obtained on a surface thereby providing nano coating on the surface. The fused electrode material includes oxides of the predefined inorganic material. The three dimensional array format is adapted to provide non-uniform deposition of the fused electrode material on the surface.

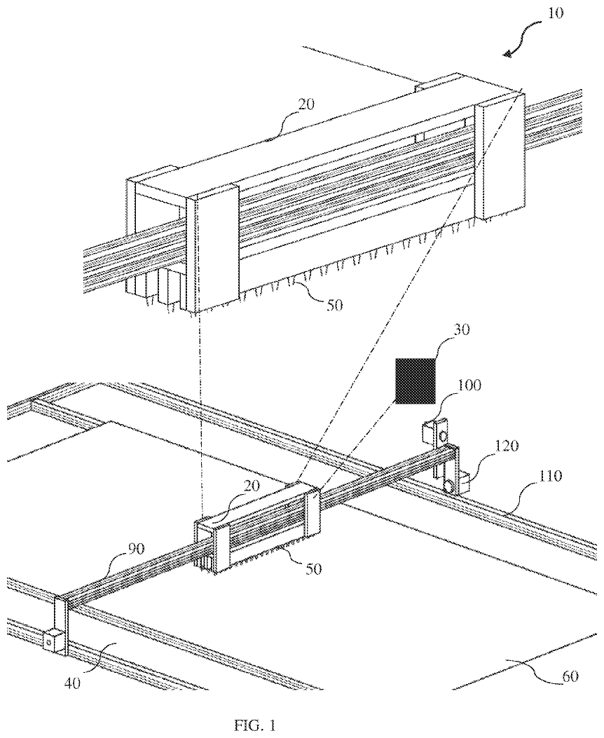

FIG. 1 is a schematic representation of an apparatus (10) for providing nano coating on a surface (60) in accordance with an embodiment of the present disclosure. The apparatus (10) includes a spark head unit (20) electrically coupled to a voltage source (30) and mounted on a frame (40). In a specific embodiment, the frame (40) may be detachably mounted over a surface (60) as per operational convenience. In one embodiment, the voltage source (30) may include, an alternating current (AC) voltage source, a direct current (DC) voltage source. In an exemplary embodiment, the voltage source (30) may provide direct current voltage between 20 kV and 40 kV. In some embodiments, the frame (40) may be composed of aluminum or graphite. In a specific embodiment, the frame (40) may include one or more motors and corresponding guide rails to provide multi-dimensional movement to the spark head unit (20).

Also, in one embodiment, the multi-dimensional movement may include, but not limited to, a two dimensional movement, a three dimensional movement and the like. In such an embodiment, the one or more motors may be controlled by a multi axis controller. In an exemplary embodiment, the multi axis controller may be a two axis controller capable of providing x-y tracking to the spark head unit (20). In a specific embodiment, a first rail (90) and a first motor (100) may provide cross travel motion to the spark head unit (20). In some embodiments, a second rail (110) and a second motor (120) may provide long travel motion to the spark head unit (20).

Further, the spark head unit (20) includes one or more electrode pairs (50) composed of a predefined inorganic material. In one embodiment, the predefined inorganic material may include at least one of a material comprising zinc, titanium tungsten and silica. In such an embodiment, purity of the material may be between 97% and 100%. The one or more electrode pairs (50) are mounted on the spark head unit (20) in a three dimensional array format. The one or more electrode pairs (50) are adapted to provide a spark between electrodes of the corresponding one or more electrode pairs (50) to obtain a fused electrode material upon receiving a voltage from the voltage source (30).

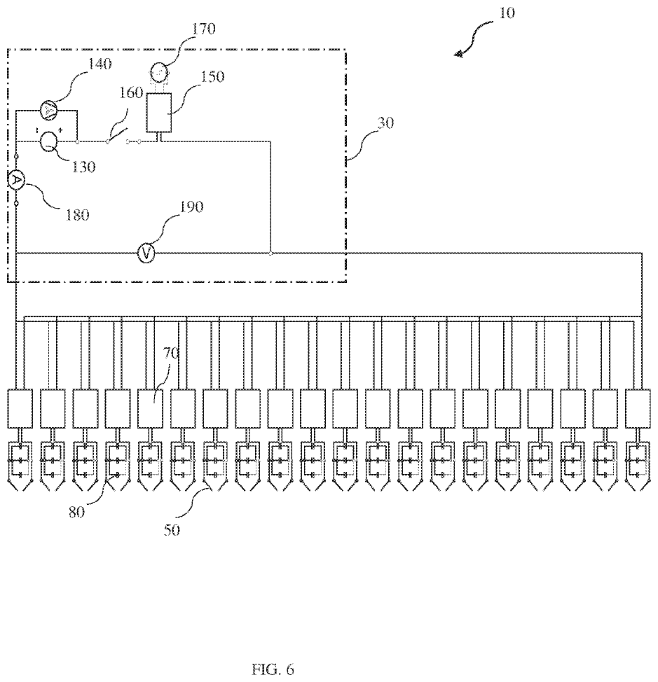

Furthermore, in some embodiments, the electrodes may have dimeters in range of 0.3 milli meters and 0.5 milli meters. In a specific embodiment, the spark head unit (20) may include one or more ceramic capacitators (not shown in FIG. 1) to restrict sparking between tips of the electrodes of the corresponding one or more electrode pairs (50). In one embodiment, the spark head unit (20) may be mounted on a robotic structure to provide remote operation. The one or more electrode pairs (50) are also adapted to deposit the fused electrode material obtained on a surface (60) thereby providing nano coating on the surface (60). In one embodiment, the spark head unit (20) may include one or more pulse coils (FIG. 6, 70) adapted to provide voltage pulses of varying duration to the corresponding one or more electrode pairs (50) to provide pulsated sparking of the one or more electrode pairs (50). In such an embodiment, thickness of the electrode material deposited on the surface (60) may depend on a duration of the voltage pulses. In one embodiment, the spark head unit (20) may include a cooling device to dissipate heat generated in the spark head unit (20).

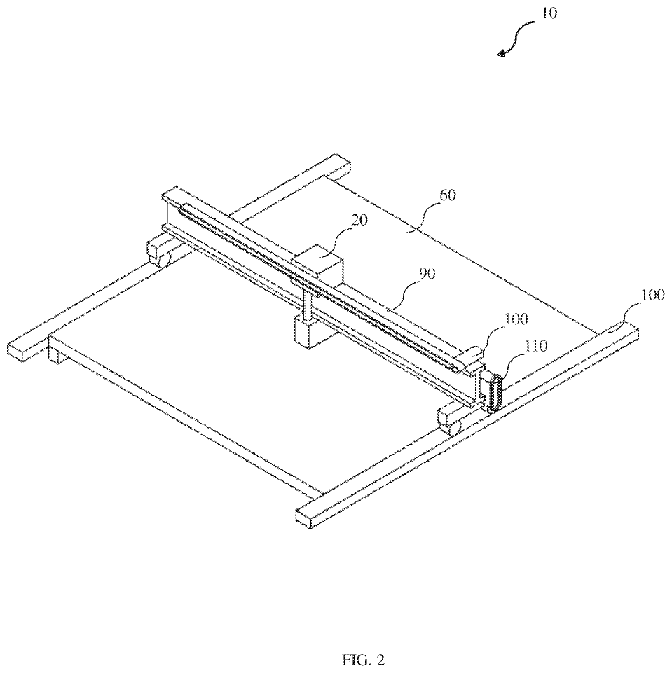

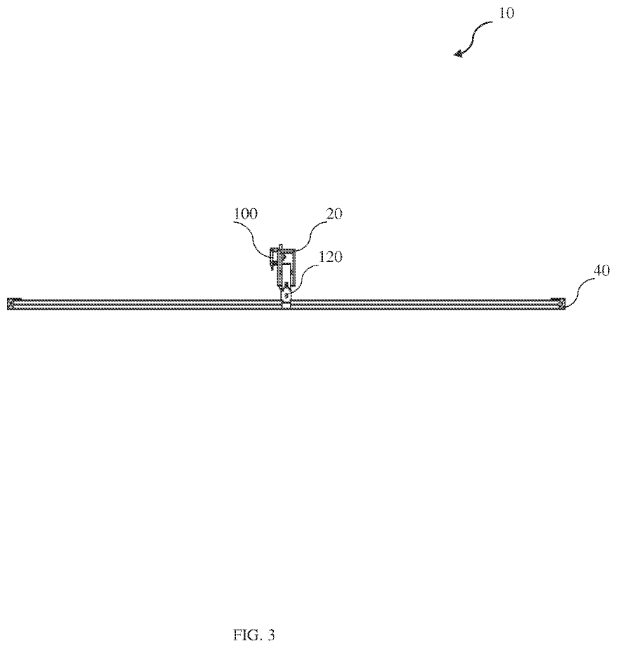

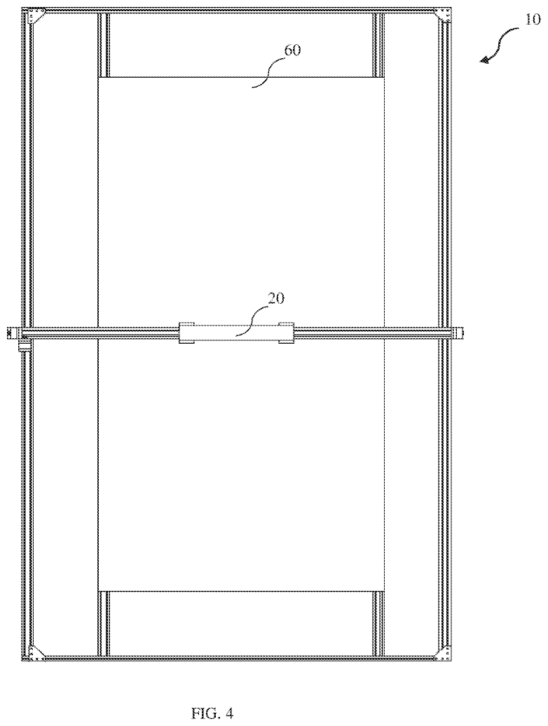

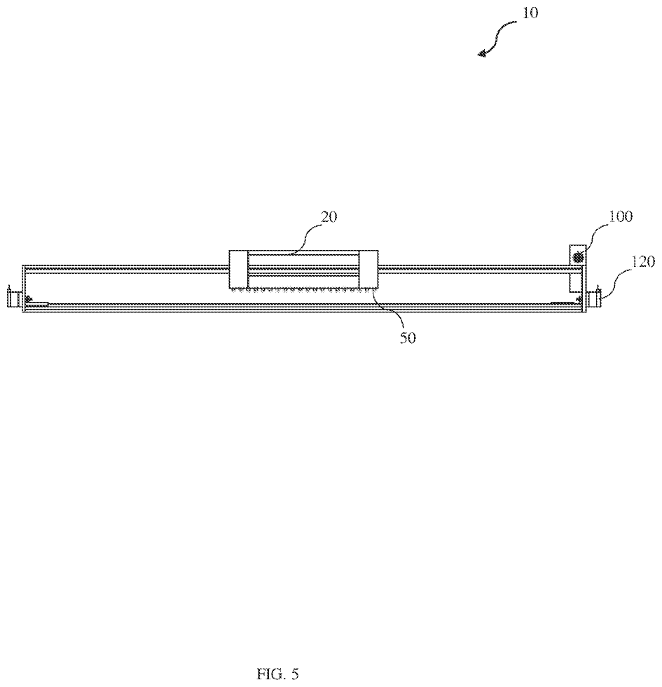

Moreover, the fused electrode material includes oxides of the predefined inorganic material. In one embodiment, the surface (60) may include, but not limited to, solar panels, wind shield of a vehicle, windowpanes, glass façade of buildings and the like. In a specific embodiment, spark head unit (20) may include one or more actuators adapted to adjust a distance between the surface (60) and the one or more electrode pairs (50). In one embodiment, the one or more actuators may include, but not limited to, an ac motor, a de motor, a stepper motor, a servo motor and the like. The three dimensional array format is adapted to provide non-uniform deposition of the fused electrode material on the surface (60). In one embodiment, the nano coating on the surface (60) may include spikes varying in thickness between 200 nano meters and 500 nanometers. Isometric view, side view, top view and front view of the spark head unit (20) is shown in FIG. 2, FIG. 3, FIG. 4, and FIG. 5 respectively. Circuital arrangement of the voltage source (30), the spark head unit (20), the one or more ceramic capacitors (80), and the one or more pulse coils (70) are described in detail in FIG. 6.

FIG. 6 is a schematic representation of yet another embodiment of the apparatus (10) of FIG. 1, depicting circuital arrangement of the spark head unit (20), the voltage source (30), the one or more ceramic capacitors (80), and the one or more pulse coils (70). In one embodiment, the voltage source (30) may include a direct current voltage source (130). In one embodiment, the direct current voltage source (130) may include, but not limited to, a direct current adapter or a rectifier electrically coupled to an alternating current power supply. In some embodiments, the alternating current power supply may be single phase or three phase. In a specific embodiment, the alternating current power supply may provide output voltage in ranges of 120 volts to 440 volts. In an exemplary embodiment, output of the direct current voltage source (130) may be 8 v 7.5 A. In one embodiment, a cooling fan (140) may be associated with the direct current voltage source (130) to provide cooling to the direct current voltage source (130). In some embodiments, a voltage multiplier (150) may be electrically coupled to the direct current voltage source (130) via a switch (160) to step up the direct current voltage provided by the direct current voltage source (130).

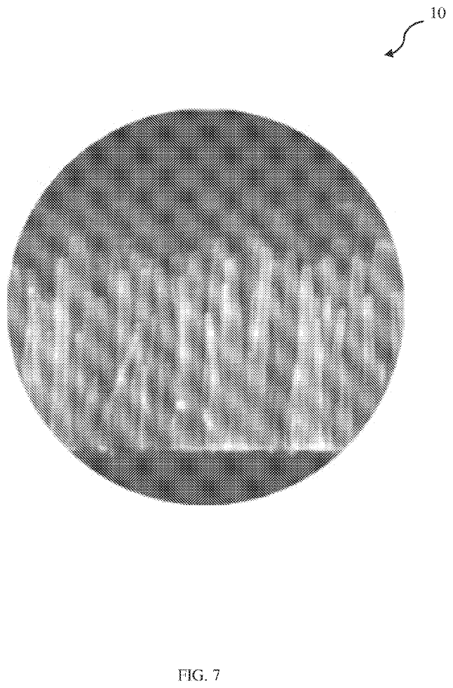

Further, in one embodiment, the voltage multiplier (150) may be receiving control signals from a control unit (170). In an exemplary embodiment, output of the voltage multiplier (150) may be between 20 kilo volts and 40 kilo volts. In such an embodiment, the voltage multiplier (150) may include, but not limited to, a voltage doubler, a voltage tripper, a voltage quadrupler and the like. In one embodiment, the one or more pulse coils (70), the one or more ceramic capacitors (80), and the one or more electrode pairs (50) may be electrically coupled to the voltage multiplier (150). In one embodiment, the voltage source may include an ammeter (180) and a voltmeter (190) to measure voltage and current provided by the voltage multiplier (150) respectively. In an exemplary embodiment, operating voltage of the one or more pulse coils (70) may be between 3.6 v DC and 6 V DC. In such an embodiment, operating current of the one or more pulse coils (70) may be 1.5 A. In one embodiment, resistance of the one or more pulse coils (70) may be 20 k ohms. Microscopic view of the nanocoating on the surface is shown in FIG. 7.

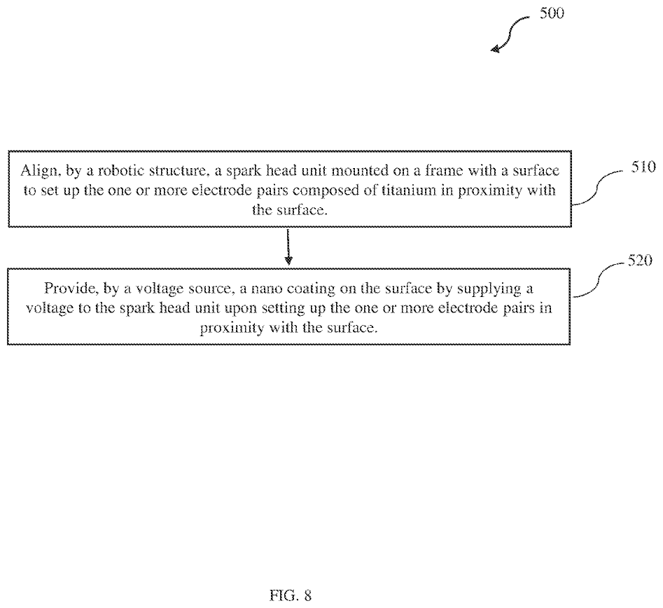

FIG. 8 is a flow chart representing the steps involved in a method (500) for providing nano coating on a surface in accordance with an embodiment of the present disclosure. The method includes aligning a spark head unit mounted on a frame with a surface to set up the one or more electrode pairs composed of a predefined inorganic material in proximity with the surface in step 510. In one embodiment, aligning a spark head unit mounted on a frame with a surface to set up the one or more electrode pairs composed of a predefined inorganic material in proximity with the surface includes aligning a spark head unit mounted on a frame with a surface to set up the one or more electrode pairs composed of a predefined inorganic material in proximity with the surface by a robotic structure.

Further, in a specific embodiment, the frame may be detachably mounted over a surface as per an operational requirement. In one embodiment, the frame may be composed of aluminum or graphite. In some embodiments, the frame may include one or more motors and corresponding guide rails to provide multi-dimensional movement to the spark head unit. In one embodiment, the multi-dimensional movement may include, but not limited to, a two dimensional movement, a three dimensional movement and the like. In such an embodiment, the one or more motors may be controlled by a multi axis controller. In an exemplary embodiment, the multi axis controller may be a two axis controller capable of providing x-y tracking to the spark head unit. In a specific embodiment, a first rail and a first motor may provide cross travel motion to the spark head unit.

Also, in some embodiments, a second rail and a second motor may provide long travel motion to the spark head unit. In one embodiment, the predefined inorganic material may include at least one of a material comprising zinc, titanium tungsten and silica. In such an embodiment, purity of the material may be between 97% and 100%. In one embodiment, the one or more actuators may include, but not limited to, an ac motor, a de motor, a stepper motor, a servo motor and the like. In one embodiment, the one or more electrode pairs may include corresponding electrodes including diameters in range of 0.3 milli meters and 0.5 milli meters. In a specific embodiment, the spark head unit may include one or more ceramic capacitators to restrict sparking between tips of the electrodes of the corresponding one or more electrode pairs. In one embodiment, the robotic structure may enable remote operation of the spark head unit.

The method (500) also includes providing a nano coating on the surface by supplying a voltage to the spark head unit upon setting up the one or more electrode pairs in proximity with the surface. In one embodiment, providing a nano coating on the surface by supplying a voltage to the spark head unit upon setting up the one or more electrode pairs in proximity with the surface includes providing a nano coating on the surface by supplying a voltage to the spark head unit upon setting up the one or more electrode pairs in proximity with the surface by a voltage source in step 520. In one embodiment, the voltage source may include, an alternating current (AC) voltage source, a direct current (DC) voltage source. In an exemplary embodiment, the voltage source may provide direct current voltage between 20 kv and 40 kv.

Further, in one embodiment, the spark head unit may include one or more pulse coils adapted to provide voltage pulses of varying duration to the corresponding one or more electrode pairs to provide pulsated sparking of the one or more electrode pairs. In such an embodiment, thickness of the electrode material which is being deposited on the surface may depend on a duration of the voltage pulses. In one embodiment, the spark head unit may include a cooling device or heat sinks to dissipate heat generated in the spark head unit. In one embodiment, the surface may include, but not limited to, solar panels, wind shield of a vehicle, windowpane, glass façade of buildings, and the like. In a specific embodiment, spark head unit may include one or more actuators adapted to adjust a distance between the surface and the one or more electrode pairs. In one embodiment, the nano coating on the surface may include spikes varying in thickness between 200 nano meters and 500 nano meters.

Various embodiments of the apparatus and a method for providing nano coating on a surface described above enable various advantages. The spark head unit provides the nano coating on the surface. Provision of the nano coating on the surface enables controlling the amount of the light reflected by the surface, the amount of the light scattered by the surface, and the amount of the light transmitted through the surface thereby enabling efficient utilization of the light falling on the surface. The nano coating also provides self-cleaning capability to the surface thereby eliminating need of allocating resources for cleaning the surface and thus reducing regular maintenance expenses for cleaning. The frame is movable thereby providing flexibility to the spark head unit to provide the nano coating irrespective of the position of the surface. Provision of the one or more motors enables the multidimensional movement of the spark head unit, thereby providing effective deposition of the electrode material on the surface.

It will be understood by those skilled in the art that the foregoing general description and the following detailed description are exemplary and explanatory of the disclosure and are not intended to be restrictive thereof. While specific language has been used to describe the disclosure, any limitations arising on account of the same are not intended.

The figures and the foregoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, the order of processes described herein may be changed and are not limited to the manner described herein. Moreover, the actions of any flow diagram need not be implemented in the order shown; nor do all the acts need to be necessarily performed. Also, those acts that are not dependent on other acts may be performed in parallel with the other acts. The scope of embodiments is by no means limited by these specific examples.

I claim:

1. An apparatus (10) for providing nano coating on a surface comprising:
a spark head unit (20) electrically coupled to a voltage source (30) and mounted on a frame (40), wherein the spark head unit (20) comprises one or more electrode pairs (50) composed of a predefined inorganic material, wherein the one or more electrode pairs (50) are mounted on the spark head unit (20) in a three dimensional array formal,
wherein the one or more electrode pairs (50) are adapted to:
provide a spark between electrodes of the corresponding one or more electrode pairs (50) to obtain a fused electrode material upon receiving a voltage from the voltage source (30), where; and
deposit the fused electrode material obtained on a surface (60), thereby providing nano coating on the surface (60), wherein the fused electrode material comprises oxides of the predefined inorganic material,
wherein the three dimensional array format is adapted to provide non-uniform deposition of the fused electrode material on the surface (60).

2. The apparatus (10) as claimed in claim 1, wherein the predefined organic material comprises least one of a material comprising zinc, titanium, tungsten and silica.

3. The apparatus (10) as claimed in claim 1, wherein the frame (40) comprises one or more motors and corresponding guide rails to provide multi-dimensional movement to the spark head unit (20), wherein the one or more motors are controlled by a multi axis controller.

4. The apparatus (10) as claimed in claim 1, wherein the spark head unit (20) comprises one or more actuators adapted to adjust a distance between the surface (60) and the one or more electrode pairs (50).

5. The apparatus (10) as claimed in claim 1, wherein the spark head unit (20) comprises one or more pulse coils (70) adapted to provide voltage pulses of varying duration to the corresponding one or more electrode pairs (50) to provide pulsated sparking of the one or more electrode pairs (50).

6. The apparatus (10) as claimed in claim 1, wherein the spark head unit (20) comprises one or more ceramic capacitators (80) to restrict sparking between tips of the electrodes of the corresponding one or more electrode pairs (50).

7. The apparatus (10) as claimed in claim 1, wherein the electrodes comprises dimeters varying in range of 0.3 milli meters and 0.5 milli meters.

8. The apparatus (10) as claimed in claim 1, wherein the spark head unit (20) is mounted on a robotic structure to provide remote operation.

9. The apparatus (10) as claimed in claim 1, wherein the nano coating on the surface (60) comprises spikes varying in thickness between 200 nano meters and 500 nano meters.

10. A method (500) comprising:
aligning, by a robotic structure, a spark head unit mounted on a frame with a surface to set up the one or more electrode pairs composed of an inorganic material in proximity with the surface; (510) and
providing, by a voltage source, a nano coating on the surface by supplying a voltage to the spark head unit upon setting up the one or more electrode pairs in proximity with the surface. (520)
